(19) United States
(12) Patent Application Publication
(10) Pub. No.: US 2019/0230740 A1
(43) Pub. Date: Jul. 25, 2019

(54) A NODE FOR A COMMUNICATIONS SYSTEM

(71) Applicant: Cambridge Communication Systems Limited, Cambridge (GB)

(72) Inventors: John David Porter, Cambridge (GB); Richard Mark Barden, Cambridge (GB)

(21) Appl. No.: 16/330,521

(22) PCT Filed: Sep. 6, 2017
(86) PCT No.: PCT/GB2017/052593

§ 371 Date: Mar. 5, 2019

(30) Foreign Application Priority Data
Sep. 6, 2016 (GB) 1615119.3

(51) Int. Cl. H04W 88/08; H04W 56/00; H04W 88/12; H04W 72/04; H04J 3/06; H03L 7/08

(52) U.S. Cl. CPC H04W 88/08; H04W 56/0015; H04W 88/12; H04W 84/20; H04J 3/0658; H03L 7/0805; H04W 72/0446

(57) ABSTRACT

A node (50) for a communications system comprising a network of a plurality of nodes is described. The node (50) communicates with other nodes (50) in the network using information formatted into superframes comprising a plurality of symbols in which part of the superframes are for payload data and part of the superframes are for synchronisation data and such that there is agreement amongst at least some nodes of the network of when a superframe starts and the duration of the symbols of the superframe. The node (50) synchronises its reference source (60,61) to a selected synchronisation source selected from external synchronisation sources and changes the selection of external synchronisation source from time to time such that the selected synchronisation source availability and reliability is above a predetermined level and communications data of a superframe is interpretable while the node (50) communicates with at least some of the other nodes (50) in the network.

### FIELD OF THE INVENTION

This invention relates to a node for a communications system.

### BACKGROUND OF THE INVENTION

Wireless communication is widely used in the developed world. For example, mobile telephones are virtually ubiquitous and are commonly carried by their users at all times. Advances in wireless technology have resulted in a progression in the use of wireless standards from the original analogue service, through GSM, 3G, 4G to emerging 5G and related standards. These standards have led to the development of ever more capable handheld devices.

In conjunction with the advances in technology required of the handset, the increased usage of mobile phones and the more data intensive services that are now commonly used has led to an increased load on the network providing the wireless service. A mobile phone wireless network has been typically configured as a set of wireless base stations that cover one or more cells that are then connected into a wired backbone telecommunication service. As more and more demand is placed on the wireless network, base stations are sited closer together with smaller cells. In urban areas in particular, given the high density of users, the locating of base stations is becoming a significant technical problem, given that a base station must have a connection into the wired backbone telecommunication service. Providing a wired connection to the backbone telecommunications service from each small cell may be difficult and costly. An alternative is to use a wireless mesh network to link the small cells to the wired backbone. UK patent application with publication No. GB2512858 describes the antenna arrangement of a wireless node of this arrangement. The node provides a high capacity wireless backhaul link directly or via one or more similar nodes to a point where wired connection can more easily be provided. The wired connection to the backbone telecommunications service may be over copper or optical fibre.

An important aspect of almost all wireless backhaul links is the use of directional antennas. All directional antennas work by focussing the radiation in one, desired, direction and reducing radiation in other undesired directions. The gain of the antenna is a direct factor of the ratio of the stereo angle served by the main beam to the full surface of a sphere. The advantages of a directional antenna are an increase in the level of the wanted signal (antenna gain) and a reduction in interference to other off-beam links. The narrower the beam, the higher will be the gain. The increased signal level resulting from the antenna gain delivers greater range, link bandwidth or both. The disadvantage of a directional antenna is the need to ensure that it is pointing in the right direction. Conventional point-to-point microwave backhaul links rely on manual alignment of individual antennas for each link at the time of link installation. This adds time and cost to the installation process and also is at risk of degradation or lose of the communications link if the equipment moves, for example due to swaying of the lamppost on which the equipment is mounted. The solution described in UK patent application with publication No. GB2512858 uses a multiplicity of switched narrow antennas to cover an angle of up to 270 degrees around a node. This retains the advantage of directional antennas but eliminates the need for manual alignment. An algorithm within the system selects the optimum antenna for each link. Adequate gain is achieved by narrowing the antenna pattern as much as possible in both vertical and horizontal planes. FIG. 1 shows the internal antenna structure of the node or unit 1 described in UK patent application with publication No. GB2512858 with its radome removed. The antennas 2,4 (in use, within a radome) of the wireless node are arranged in two layers (reference numerals are only used to highlight some of the antennas in FIG. 1 for clarity) with alternate antennas on upper layers (antennas 2) and lower layers (antennas 4). The provision of the antennas in two different horizontal planes means that antennas can be selected in a transmitting mode and a receiving mode so that the likelihood of destructive interference from a reflected signal path is reduced.

FIG. 2 shows the node 1 of FIG. 1 with the radome 6 in place that conceals and provides protection to the antenna structure (that is not visible in FIG. 2).

A mesh network includes a plurality of this type of node and each node of the network relays data for the network and the nodes cooperate in the distribution of data around the network. In spatial time division multiple access (STDMA) systems such as used in this mesh network, data communications between nodes is organised according to a schedule which defines when pairs of nodes transmit and receive. This ensures that bandwidth in the STDMA system is efficiently used whilst avoiding collisions (interference) between links. In STDMA systems, the transmitted signal is formed in superframes. That is to say, the transmitted signal includes data that is framed by alignment signals which are distinctive bit sequences or words distinguished from data bits that allow data within the frame to be extracted for decoding or retransmission. The slots for these data transmissions are arranged in superframes according to the needs of the schedule, which also includes management bearers, interference measurement opportunities and allowance for propagation delay (so for a transmission slot on a link, the corresponding reception slot will be scheduled at some time later which equals the one-way propagation delay of the link).

An example superframe 10 is illustrated in FIG. 3. In this example, the timing in the system is arranged in superframes each with a duration of exactly one second. Each superframe is divided into a number of slots, some of which are reserved for specific purposes. Data is transmitted as symbols lasting 10 ns, so a superframe in this example contains 10⁸ symbols. A symbol represents an integer number of bits. Each superframe starts and ends with a dead period 12,14 (the start dead period is reference numeral 12, the end dead period is reference numeral 14) of 10 μs. Particular groups of symbols in particular positions in the superframe have particular meanings For example, a poll channel slot is a group of symbols that always occurs in the same position in the superframe and is used to communicate information that is used to help identify and synchronise neighbouring nodes, whereas STDMA macros slots occur at other positions in the superframe, and are used to carry user data. In summary a known superframe includes a fixed number of symbols, and the position of specific groups of symbols in a superframe provides the context for interpreting those symbols. Frequency and phase synchronisation are derived from the same timing source, and synchronisation is achieved before a viable communications link to carry user data can be established.

The vast majority of a superframe is used for carrying user data in bearer slots 16 (only some of which are labelled in FIG. 3 for clarity). Some slots at particular locations in the superframe are however reserved. Their function always occurs at the same time offsets in the superframe. For synchronisation purposes, two types of slot are of interest: Poll Channel slots 18; and Registration Channel slots in a cluster 20. The example of FIG. 3 is a schematic and there are actually 256 Poll Channel slots in a superframe between clusters of Registration Channel slots or between a dead period and a cluster of Registration Channel slots. There are five clusters each of six Registration Channel slots (30 slots in total). Poll Channel slots and Registration Channel slots (RegChans) are both slow bearers. In other words, they carry content at a low communication rate or bit rate (e.g. the RegChans bit rate is approximately 9 kb/s per node). For successful communications, each node has to use the same symbol period as other nodes, to successfully recover sequences of symbols, and must know when a superframe starts, in order to correctly interpret the symbols. Therefore synchronisation requires: frequency alignment (the node frequency reference must be accurately aligned so that the symbol clock is consistent with other nodes); and phase alignment of the superframe boundary.

It is an important requirement of backhaul links (both wired and wireless), that they remain highly available at all times. By this it is meant that the equipment using the links must be able to successfully transmit data, at the required throughput speed (for example, 100 Mbits per second) at all times, to the desired destination. This requirement is often described as “five nines” or “six nines” availability, which is that the full capacity of the backhaul link must be available 99.999% of the time, or 99.9999% of the time respectively.

It is a further requirement, particularly for more advanced communications systems, that the latency of data communications links is kept low, within limits prescribed by the communications protocols being used.

### BRIEF SUMMARY OF THE INVENTION

It is an object of embodiments of the present invention to address the problem of synchronising the timing of messages between nodes of a network and, in particular, a wireless backhaul network or mesh network.

Embodiments of the present invention achieve significant improvements to the robustness and capabilities of synchronisation between nodes of a network and, in particular, a wireless backhaul network or mesh network. In particular they: receive and switch between multiple synchronisation sources without dropping communications links; acquire synchronisation from other nodes in the network; operate without any external synchronisation source; transport synchronisation across a network including decoupling frequency and phase synchronisation from each other; and/or achieve interference coordination between nodes in different synchronisation domains.

Nodes of a network of a plurality of nodes of examples of the present invention communicate with other nodes in the network using information formatted into superframes and there is agreement amongst at least some of the nodes of the network when a superframe starts and the duration of the symbols of the superframe and communications data of the superframe is interpretable while the node communicates with at least some of the other nodes in the network. In other words, significantly, in examples of the present invention, a node synchronises with other nodes while the nodes continue to communicate with one another. There is no break in communication between nodes while they synchronise. The node maintains data throughput capacity with at least some of the other nodes in the network while it synchronises. This results in very reliable communications between nodes of the network, which is particularly important for a wireless backhaul network.

The invention in its various aspects is defined in the independent claims below to which reference should now be made. Advantageous features are set forth in the dependent claims.

Arrangements are described in more detail below and take the form of a node for a communications system comprising a network of a plurality of nodes. The node communicates with other nodes in the network using information formatted into superframes comprising a plurality of symbols in which part of the superframes are for payload data and part of the superframes are for synchronisation data and such that there is agreement amongst at least some nodes of the network of when a superframe starts and the duration of the symbols of the superframe. The node synchronises its reference source to a selected synchronisation source selected from external synchronisation sources and changes the selection of external synchronisation source from time to time such that the selected synchronisation source availability and reliability is above a predetermined level and communications data of a superframe is interpretable while the node communicates with at least some of the other nodes in the network.

The two requirements described above of high availability and low latency, together and separately, require that the backhaul link maintains undisturbed communications at all times or, in other words, each node of the network must maintain data throughput capacity with at least some of the other nodes in the network. By this it is meant, that there must be no errors, packet loss or increase in latency (above the desired limits) at any time. Specifically, from the synchronisation perspective, this means that even when the synchronisation source is being changed, the communication link must be maintained, with user data passing over it. No loss and re-establishment of the link is permitted, nor any significant increase in latency (above the prescribed limit). This may be provided by the arrangements described herein.

In an example, the network which forms a synchronous communications network may comprise a plurality of wireless nodes each equipped with a local synchronisation source which may or may not be active. The plurality of wireless nodes may each be equipped with a GPS connection. This provides accurate frequency reference and frame timing, in which timing of messages across the network can maintain synchronisation in the event of failure of GPS at one or more nodes. Synchronisation may be maintained even while the nodes of the network continue to communicate with one another or transmit and receive data from other nodes. Any of the wireless nodes may provide an accurate frequency and timing reference to external equipment. The frequency reference to external equipment may be provided by the use of Synchronous Ethernet. Synchronisation over the network may be achieved by measuring the time of arrival of a fixed data sequence together with transmission of measurements of timing offset between nodes. Local frequency reference may be maintained in each wireless node and phase-locked to the best available timing source derived from GPS, Synchronous Ethernet, IEEE 1588-2008 data packets or timing signals derived from the broadband data link between nodes. Each node may transmit a message indication of the quality of its synchronisation and a node receiving such messages may use them to decide which timing source it should use to obtain synchronisation. A third party clock may be transported across the network.

In an aspect of the present invention, there is provided a node for a communications system comprising a network of a plurality of nodes, the node being configured to communicate with other nodes in the network using information formatted into superframes comprising a plurality of symbols in which part of the superframes are for payload data and part of the superframes are for synchronisation data and such that there is agreement amongst at least some nodes of the network of when a superframe starts and the duration of the symbols of the superframe: the node comprising a reference source; and the node being configured to receive external synchronisation information from external synchronisation sources in the form of part of the superframes comprising a plurality of symbols received from the external synchronisation sources; wherein the node is configured to: synchronise the reference source to a selected synchronisation source selected from the external synchronisation sources and to change the selection of external synchronisation source from time to time such that the selected synchronisation source availability and reliability is above a predetermined level such that the reference source provides agreement amongst at least some of the nodes of the network when a superframe starts and the duration of the symbols of the superframe and communications data of the superframe is interpretable while the node communicates with at least some of the other nodes in the network.

The node may further comprise an internal synchronisation source; and the internal synchronisation source is configured to form a selected synchronisation source. If it is not possible that the selected synchronisation source availability and reliability is above a predetermined level, the node may be configured to synchronise with the internal synchronisation source and communications data of a superframe is interpretable until the reliability of the internal synchronisation source falls below a predetermined level. The internal synchronisation source may comprise a satellite positioning system receiver, such as global positioning system, GPS, receiver. The external synchronisation sources may comprise at least one of: a signal received from another node in the same network as the node; and a wired connection of the node. The wired connection to the nodes may be for a synchronous ethernet, SyncE, signal. The wired connection to the node may be for a precision time protocol, PTP, signal. The reference source may comprises a clock to determine when a superframe starts and a local frequency reference source, such as a voltage controlled crystal oscillator, VCXO, to determine the duration of the symbols of a superframe.

In another aspect of the present invention, there is provided a node for a communications system comprising a network of a plurality of nodes, the node being configured to: communicate with other nodes in the network using information formatted into superframes comprising a plurality of symbols in which part of the superframes are for payload data and part of the superframes are for synchronisation data and such that there is agreement amongst at least some nodes of the network of when a superframe starts and the duration of the symbols of the superframe; wherein different superframes comprise different numbers of symbols and each at least some of the superframes comprise a plurality of indications of the number of symbols in the superframe spaced apart at different portions of the superframe; and receive external synchronisation information from separate sources in relation to when a superframe starts and the duration of the symbols of the superframe, such that the node is synchronised with at least some of the other nodes in the network in relation to when a superframe starts and the duration of the symbols of the superframe while the node communicates with at least some of the other nodes in the network.

The source the node is configured to receive external synchronisation information from in relation to when a superframe starts may comprise a precision time protocol, PTP, signal. The source the node is configured to receive external synchronisation information from in relation to duration of the symbols of the superframe may comprise a synchronous ethernet, SyncE, signal. The node may comprise a reference source; and the node may be configured to synchronise the reference source based on the external synchronisation information. The reference source may comprise a clock to determine when a superframe starts and a local frequency reference source, such as a voltage controlled crystal oscillator, VCXO, to determine the duration of the symbols of a superframe. The node may comprise a phase locked loop and the node may be configured to synchronise the reference source based on the external synchronisation information using the phase locked loop. The phase locked loop may comprise a controller that uses a correction signal to control the phase locked loop. The controller may stepwise control the correction signal over time. The controller may comprise a proportional integrator controller. the node comprises a reference source. The node may be configured to synchronise the reference source to a selected synchronisation source selected from a plurality of external synchronisation sources and to change the selection of external synchronisation source from time to time such that the selected synchronisation source availability and reliability is above a predetermined level such that the reference source provides agreement amongst at least some of the nodes of the network when a superframe starts and the duration of the symbols of the superframe and communications data of the superframe is interpretable while the node communicates with at least some of the other nodes in the network. The node may further comprise an internal synchronisation source. The internal synchronisation source may be configured to form a selected synchronisation source. If it is not possible that the selected synchronisation source availability and reliability is above a predetermined level, the node may be configured to synchronise with the internal synchronisation source and communications data of a superframe is interpretable until the reliability of the internal synchronisation source falls below a predetermined level. The internal synchronisation source may comprise a satellite positioning system receiver, such as global positioning system, GPS, receiver. The external synchronisation sources may comprise at least one of: a signal received from another node in the same network as the node; and a wired connection of the node.

In another aspect of the present invention, there is provided a node for a communications system comprising a network of a plurality of nodes, the node comprising a reference source and being configured to receive external synchronisation information from an external synchronisation source to synchronise the reference source to the external synchronisation source; and wherein the node is configured to become a slave node and synchronise to a master node selected from a group of nodes of the network of the plurality of nodes of which the node is a part and to synchronise the reference source to the master node if a predetermined slave condition applies.

The predetermined slave condition may be that no node of the network node can synchronise to an external synchronisation source. The node may also be configured to become a master node and synchronise other nodes forming slave nodes to it in which the slave nodes are selected from a group of nodes of the network of the plurality of nodes of which the node is a part if a predetermined master condition applies. The node may be configured to be selected as the master node from the group of nodes as it has: access to the highest quality external synchronisation source of the group of nodes, such as a wired connection to a precision time protocol, PTP, signal or the highest quality global positioning system of the group of nodes; or a unique identifier that meets a predetermined condition, such as the unique identifier is numerically the lowest or highest of the group of nodes.

The node may be configured to communicate with nodes of different groups of nodes such that the reference source of the node is stepwise adjusted towards synchronisation with the reference sources of different groups of nodes of the network. The reference source of the node may be stepwise adjusted based on differences between reference sources and rate of change of differences between reference sources of the nodes of the different groups of the nodes of the network. The external synchronisation sources may comprise at least one of: a signal received from another node in the same network as the node; and a wired connection of the node. The wired connection to the nodes may be for a synchronous ethernet, SyncE, signal. The wired connection to the node may be for a precision time protocol, PTP, signal. The node may be configured to communicate with other nodes in the network using information formatted into superframes comprising a plurality of symbols in which part of the superframes are for payload data and part of the superframes are for synchronisation data. The node may be configured such that there is agreement amongst at least some nodes of the network of when a superframe starts and the duration of the symbols of the superframe. Different superframes may comprise different numbers of symbols. Each at least some of the superframes may comprise a plurality of indications of the number of symbols in the superframe spaced apart at different portions of the superframe. The node may be configured to receive external synchronisation information from separate sources in relation to when a superframe starts and the duration of the symbols of the superframe, such that the node is synchronised with at least some of the other nodes in the network in relation to when a superframe starts and the duration of the symbols of the superframe while the node communicates with at least some of the other nodes in the network. The reference source may comprise a clock to determine when a superframe starts and a local frequency reference source, such as a voltage controlled crystal oscillator, VCXO, to determine the duration of the symbols of a superframe. The node may be configured to synchronise the reference source to a selected synchronisation source selected from a plurality of external synchronisation sources and to change the selection of external synchronisation source from time to time such that the selected synchronisation source availability and reliability is above a predetermined level such that the reference source provides agreement amongst at least some of the nodes of the network when a superframe starts and the duration of the symbols of the superframe and communications data of the superframe is interpretable while the node communicates with at least some of the other nodes in the network. The node may further comprise an internal synchronisation source; and the internal synchronisation source is configured to form a selected synchronisation source. If it is not possible that the selected synchronisation source availability and reliability is above a predetermined level, the node may be configured to synchronise with the internal synchronisation source and communications data of a superframe is interpretable until the reliability of the internal synchronisation source falls below a predetermined level. The internal synchronisation source may comprise a satellite positioning system receiver, such as global positioning system, GPS, receiver.

In another aspect of the present invention, there is provided a node for a communications system comprising a network of a plurality of nodes, the node comprising a reference source and being configured to receive external synchronisation information from an external synchronisation source to synchronise the reference source to the external synchronisation source; and wherein the node is configured to become a master node and synchronise other nodes forming slave nodes to it in which the slave nodes are selected from a group of nodes of the network of the plurality of nodes of which the node is a part if a predetermined condition applies.

The predetermined condition may be that no node of the network node can synchronise to an external synchronisation source. The node may be configured to be selected as the master node from the group of nodes as it has access to the highest quality external synchronisation source of the group of nodes, such as a wired connection to a precision time protocol, PTP, signal or the highest quality global positioning system of the group of nodes. Nodes of different groups of nodes may communicate such that reference sources of the different groups are stepwise adjusted towards synchronisation. The reference source of the node may be stepwise adjusted based on differences between reference sources and rate of change of differences between reference sources of the nodes of the different groups of the nodes of the network.

In a yet further aspect of the present invention, there is provided a node for a communications system comprising a network of a plurality of nodes formed into groups of nodes, wherein the node comprises a reference source and wherein the node is configured to communicate with other nodes of the network of nodes such that reference sources of the nodes of different groups of nodes of the network are stepwise adjusted towards synchronisation.

The reference source of the node may be stepwise adjusted based on differences between reference sources and rate of change of differences between reference sources of the nodes of the different groups of the nodes of the network.

In another aspect of the present invention, there is provided a node for a communications system comprising a network of a plurality of nodes, the node being configured to communicate with other nodes in the network, the node comprising: a reference source to synchronise with other nodes in the network; a phase locked loop to synchronise the reference source based on synchronisation information received by the node from a source external to the node; and a controller that stepwise controls a correction signal over time to control the phase locked loop so that the reference source becomes synchronised with a different source external to the node while maintaining data throughput capacity with at least some of the other nodes in the network.

The node may communicate with other nodes in the network using information formatted into superframes comprising a plurality of symbols in which part of the superframes are for payload data and part of the superframes are for synchronisation data and each superframe spans a frame with a time period. The controller may stepwise control the correction signal over time to control the phase locked loop so that the reference source changes the source external to the node to which it is synchronised over a period of time corresponding to a plurality of frames, such as 2 to 10 frames or 3 to 7 frames. The time period may be fixed between 0.5 seconds to 3 seconds, such as 1 second or 2.5 seconds. The source external to the node may comprise a precision time protocol, PTP, signal. The source external to the node may comprise a synchronous ethernet, SyncE, signal. The reference source may comprises a clock, such as a voltage controlled crystal oscillator, VCXO. The controller may comprise a proportional integrator controller. The network described above may be a mesh network. The network may comprise a plurality of nodes as described above.

In another aspect of the present invention, there is provided a method of synchronising a node of a communications network comprising a plurality of nodes to other nodes of the communications network, the method comprising the node: communicating with at least some of the other nodes in the network using information formatted into superframes comprising a plurality of symbols in which part of the superframes are for payload data and part of the superframes are for synchronisation data; and simultaneously: determining the availability and reliability of an external synchronisation source of the node; and changing the selection of the external synchronisation source of the node if the selected synchronisation source availability and reliability is below a predetermined level such that the reference source provides agreement amongst at least some of the nodes of the network when a superframe starts and the duration of the symbols of the superframe and communications data of the superframe is interpretable.

In a further aspect of the present invention, there is provided a method of synchronising a node of a communications network comprising a plurality of nodes to other nodes of the communications network, the method comprising the node: communicating with at least some of the other nodes in the network using information formatted into superframes comprising a plurality of symbols in which part of the superframes are for payload data and part of the superframes are for synchronisation data; wherein different superframes comprise different numbers of symbols and each at least some of the superframes comprise a plurality of indications of the number of symbols in the superframe spaced apart at different portions of the superframe; and simultaneously: receiving external synchronisation information from separate sources in relation to when a superframe starts and the duration of the symbols of the superframe, such that the node is synchronised with at least some of the other nodes in the network in relation to when a superframe starts and the duration of the symbols of the superframe.

In another aspect of the present invention, there is provided a method of synchronising a node of a communications network comprising a plurality of nodes to other nodes of the communications network, the method comprising the node: receiving external synchronisation information from an external synchronisation source to synchronise a reference source of the node to the external synchronisation source; and becoming a slave node and synchronising the reference source to a master node selected from a group of nodes of the network of the plurality of nodes of which the node is a part if a predetermined slave condition applies.

In another aspect of the present invention, there is provided a method of synchronising a node of a communications network comprising a plurality of nodes to other nodes of the communications network, the method comprising the node: receiving external synchronisation information from an external synchronisation source to synchronise a reference source of the node to the external synchronisation source; and becoming a master node and synchronising other nodes forming slave nodes to it in which the slave nodes are selected from a group of nodes of the network of the plurality of nodes of which the node is a part if a predetermined condition applies.

In a yet further aspect of the present invention, there is provided a method of synchronising a node of a communications network comprising a plurality of nodes formed into groups of nodes to other nodes of the communications network, the method comprising the node: communicating with other nodes of the network of nodes such that reference sources of the nodes of different groups of nodes of the network are stepwise adjusted towards synchronisation.

In a still further aspect of the present invention, there is provided a method of synchronising a node of a communications network comprising a plurality of nodes, the node being configured to communicate with other nodes in the network, the method comprising: receiving synchronisation information from a source external to the node; synchronising a reference source of the node using a phase locked loop based on the synchronisation information received by the node from the source external to the node to synchronise with other nodes in the network; and stepwise controlling a correction signal over time to control the phase locked loop so that the reference source becomes synchronised with a different source external to the node while maintaining data throughput capacity with at least some of the other nodes in the network.

A computer program may be provide for implementing the methods described above.

A non-transitory computer readable medium comprising instructions may be provided for implementing the methods described above.

### BRIEF DESCRIPTION OF THE DRAWINGS

The invention will be described in more detail, by way of example, with reference to the accompanying drawings, in which:

FIG. 1 (prior art) is a perspective view from above of the internal components of a known node for a communications system comprising a plurality of nodes;

FIG. 2 (prior art) is a perspective view from above of the exterior of the known node of FIG. 1;

FIG. 3 (prior art) is a schematic of a superframe for communications between nodes of the type illustrated in FIGS. 1 and 2 in a network;

FIG. 4 is a schematic of nodes embodying aspects of the present invention in a network;

FIG. 5 is a schematic of a node of the network of FIG. 4;

FIG. 6 is a schematic diagram of a network of nodes of FIG. 5 embodying an aspect of the present invention;

FIG. 7 is a schematic in the form of a state diagram illustrating a method implemented on the node of FIG. 5;

FIG. 8 is a schematic of a detail of a registration channel slot to illustrate embodiments of aspects of the present invention; and

FIG. 9 is a schematic of a plurality of superframes illustrating an embodiment of an aspect of the present invention.

Like reference numerals are used to describe like features throughout the present patent application.

### DETAILED DESCRIPTION OF THE INVENTION

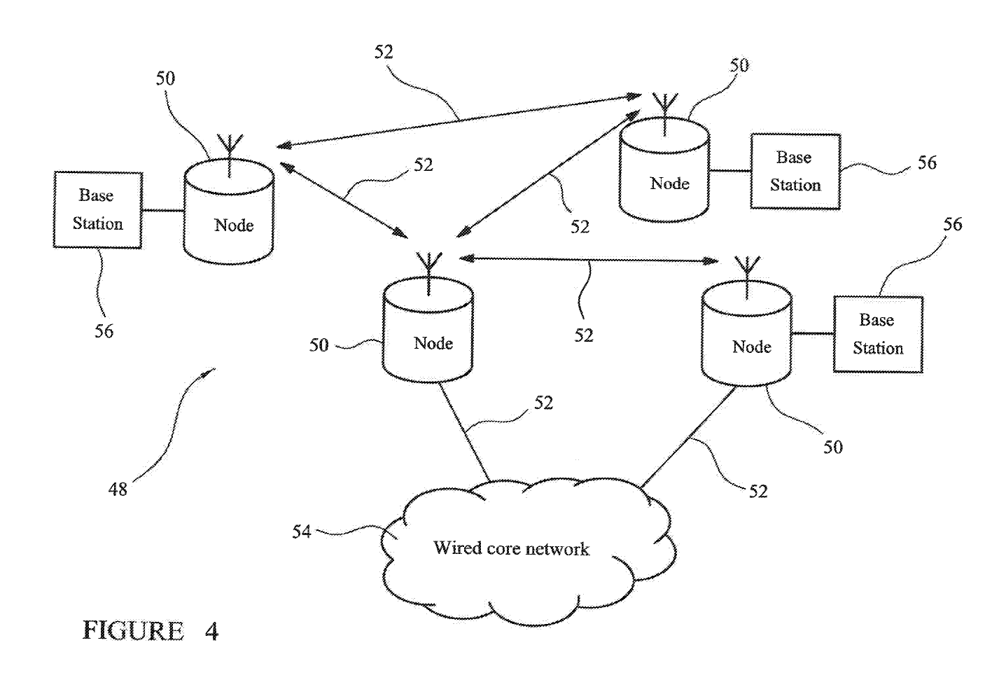

An example node 50 forming part of a network 48 of a plurality of nodes 50 of a communications system will now be described with reference to FIGS. 4 to 8.

### INTRODUCTION—SYNCHRONISATION REQUIREMENT AND TUNING MECHANISM

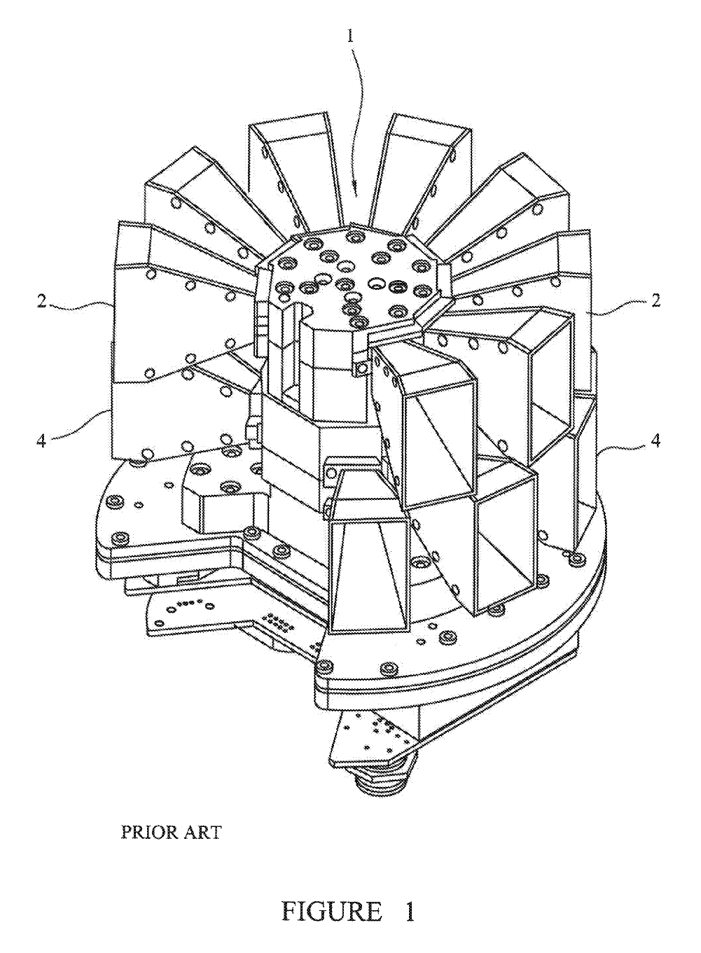

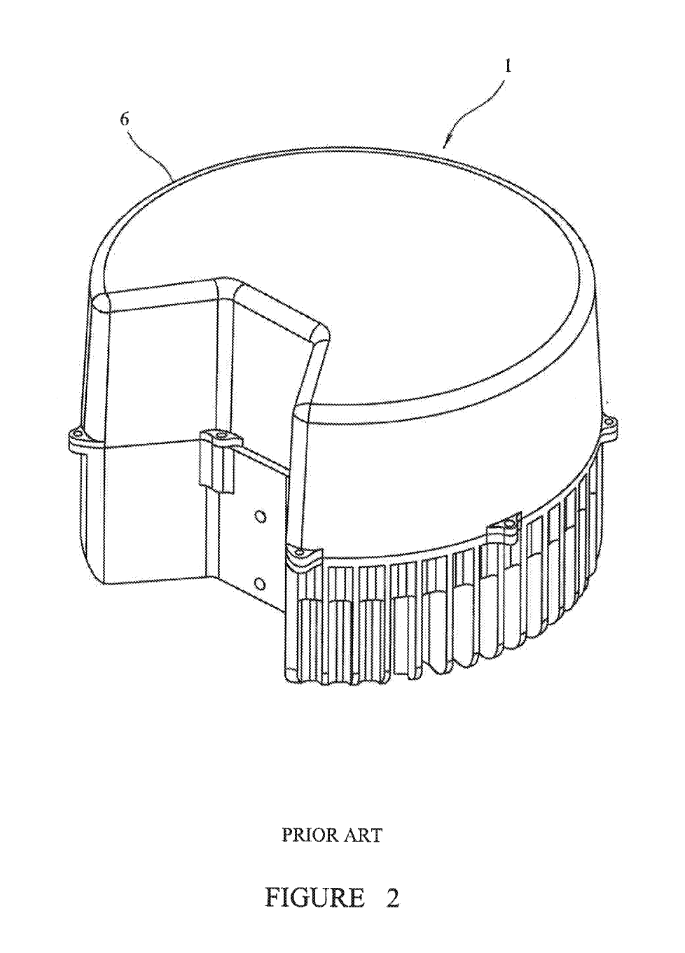

FIG. 4 broadly illustrates the network 48 of nodes 50, which in this example is a mesh network forming a wireless backhaul network. The network includes a plurality of wireless nodes 50, which are interconnected by wireless links 52. Some of the wireless nodes are connected to a wired core network 54. Base stations 56 of a mobile communications network may be connected to any of the wireless nodes, which provide a backhaul link to and from the wired core network. Each node of the network is of the type described above with reference to FIGS. 1 and 2.

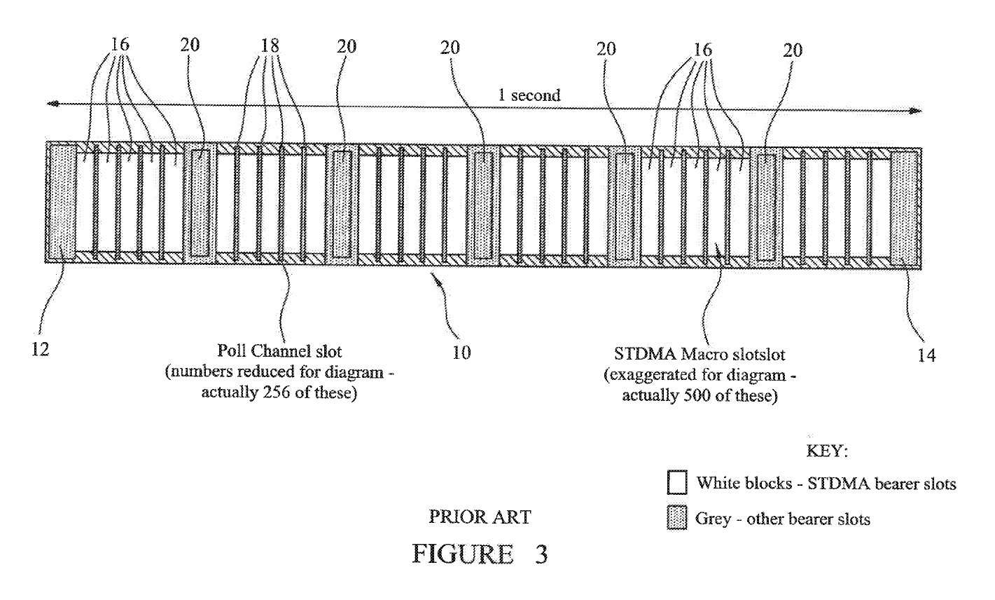

The communication between all of the wireless nodes in the network is organised in frames and, in particular superframes an example of which is shown in FIG. 3, whose timing is synchronised across the whole network. Each of the nodes is configured to synchronise itself with other nodes in the network and the arrangement to do this is described below. Strictly, under extreme circumstances, there may not always be complete synchronisation across the whole network and the arrangement described provides agreement amongst at least some nodes of the network of when a superframe starts and the duration of the symbols of the superframe or, in other words, synchronisation between at least some of the nodes of the network of nodes. The frequency of the synchronisation source determines the symbol duration, and the phase of the synchronisation source determines the timing of the start of a superframe.

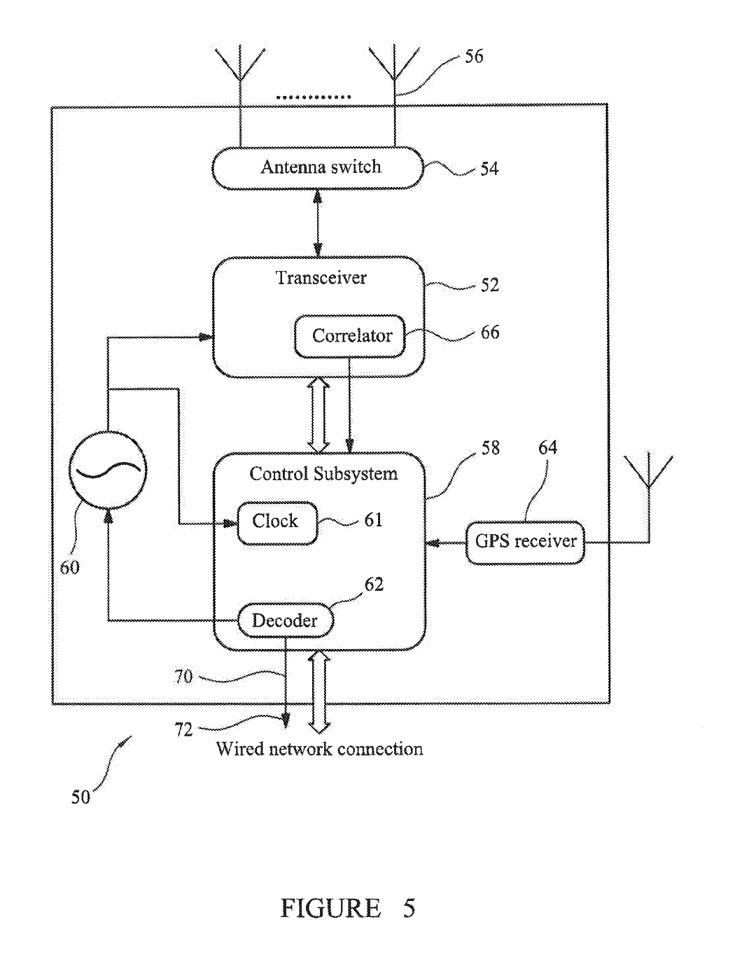

A wireless node 50 of the network of the communication system of FIG. 4 is illustrated in FIG. 5. The node comprises a transceiver 52 connected via an antenna switch 54 to a plurality of directional antennas 56 (as explained above with reference to FIGS. 1 and 2). The node includes a control subsystem 58 that controls the node including its synchronisation with other nodes in the network. The node is provided with a local frequency reference source 60 and a symbol clock 61. The control subsystem controls a small adjustment to the frequency provided by the local frequency reference source to enable it to be locked to an external frequency reference or internal frequency reference, thus establishing a phase locked loop (PLL). Synchronisation between the nodes of the network is by synchronisation of their local frequency reference sources and clocks. In this example, the local frequency reference source is a voltage controlled crystal oscillator (VCXO). The node also includes a decoder 62 of an external synchronisation signal, such as precision time protocol (PTP—a protocol that is used to synchronise clocks throughout a computer network), or PTP and Synchronous Ethernet (SyncE—a computer network standard that provides for the clock signals to be transferred over the Ethernet physical layer) or any other high accuracy synchronisation arrangement which may be provided by a wired connection to the node. The node also includes a local synchronisation source or internal synchronisation source that is a means of acquiring precise timing information. This is derived from a local global positioning system (GPS) receiver 64. The node also has a correlator 66 in a receiver part of the transceiver of the node that is able to determine the timing of the start of each frame of a fixed data sequence from the clock 61, and the symbol period of received transmissions. The node has a timing signal output 70 from which a timing signal 72 is output.

Broadly, the node 50 of FIG. 5, acting as a controller or slave node, receives external synchronisation information from the external synchronisation sources (such as sources to which the node has a wired connection, for example, Ethernet arrangements like PTP and/or SyncE) and/or a signal received from another node in the same network (acting as a master node) as the node from antenna 56 via antenna switch 54, and transceiver 52.

The control subsystem 58 of the node includes a proportional integrator controller (in this example, other means may be used). The controller synchronises the reference source or local frequency reference 60 to the selected synchronisation source selected from the external synchronisation sources and, in this example, also the internal synchronisation source derived from the GPS receiver 64, which provides a reliable one second pulse, and then changes the selection of external or, in this example, synchronisation source from time to time such that the selected synchronisation source availability and reliability is above a predetermined level as determined by the control subsystem 58. The reference source or local frequency source 60 and clock 61 then provide agreement amongst at least some of the nodes of the network when a superframe starts and the duration of the symbols of the superframe and communications data of the superframe is interpretable while, significantly, the node communicates with at least some of the other nodes in the network.

In this example, the node 50 includes an internal synchronisation source for the internal synchronisation source to synchronise with. Each node has an internal frequency reference 60 and clock 61, and it is these that are adjusted such that all nodes in a network are synchronised in terms of frequency (by adjustment of the internal frequency reference) and phase (by adjustment of the clock). In this way, nodes of the network agree on what the symbol duration is and when a superframe starts and from this they can successfully decode the transmitted bitstream and its context.

Examples of the node 50 may not synchronise with the internal synchronisation source either because it is not provided or because a reliable GPS signal may not be available to the GPS receiver 64 and so it may not be a reliable synchronisation source.

In this example, where the node 50 is provided with an internal synchronisation source, if it is not possible that the selected synchronisation source availability and reliability is above a predetermined level as determined by the control subsystem 58, the node synchronises with the internal synchronisation source and communications data of a superframe is interpretable until the reliability of the internal synchronisation source falls below a predetermined level.

Detailed features of the node 50 as controlled by the control subsystem 58 are set-out below.

### Local Synchronisation Source

Once a GPS signal (or alternative local synchronisation) has been acquired, the local frequency reference source 60 is phase-locked by the control subsystem 58 to the synchronisation source to provide an accurate frequency reference from which both the carrier frequency and symbol and frame timing of the wireless node are derived. In the event of a short-term loss of synchronisation, the local reference will continue to maintain timing, but the accuracy will gradually degrade owing to factors such as changing temperature.

Alternatively, a synchronisation source may be provided to the node 50 via a wired connection.

In this example, if a node 50 has a wired synchronisation source, this will be a Synchronous Ethernet (SyncE) connection which allows a data clock signal to be recovered, to which the local frequency reference 60 can be locked, and absolute timing at the master node can be achieved by the use of data messages transmitted across the core network according to PTP as defined in the IEEE 1588-2008 standard. If Synchronous Ethernet is not available, the controller node can derive both frequency and frame timing using PTP as defined in the IEEE 1588-2008 standard. If Synchronous Ethernet is available at the controller node but no GPS or PTP as defined by the IEEE 1588-2008 standard data is available, the controller node will define an arbitrary frame timing to which other nodes will synchronise, or alternatively use ready reckoning if it previous had phase lock (for example from a GPS reference which has now become invalid).

Maintaining Synchronisation from Neighbours

A method is provided by the control subsystem 58 of the node 50 to enable synchronisation to be maintained in the event of a long-term loss of local synchronisation source at one or more nodes. The method allows accurate frequency and phase synchronisation to be distributed over the links or nodes of the wireless network.

When nodes 50 are externally synchronised the control subsystem 58 learns or calculates the true propagation delay between each other by sharing and averaging, over direction and time, the propagation delay measurements they make. This eliminates errors due to clock differences between node pairs. Hence, when a node loses its local synchronisation source it can maintain synchronisation by controlling its local clock 61 to keep its new propagation measurements from a neighbouring node equal to the relevant average already calculated. The choice of which neighbours to lock to must avoid timing loops. This might be a neighbour which still advertises an independent synchronisation source, or it might be a prescribed topology.

Acquiring Synchronisation from Neighbours

Initial synchronisation of a node 50 is provided even if it is unable to receive a GPS signal. The node transmits a fixed data sequence in specific positions in each frame as controlled by the control subsystem via transceiver 52, antenna switch 54 and antennas 56. A node's synchronisation may be acquired from synchronised neighbour nodes. The node with a synchronisation source transmits correlation sequences on all antennas 56 at fixed positions in the superframe. A second node without synchronisation will listen on one antenna 56 at a time for these sequences. The correlator 66 in the receiver node or second node is able to determine the exact timing of the start of the sequence. The pattern of received correlation sequences is used to estimate the frequency difference between successive superframes, which can be used to frequency lock the second node's local symbol clock 61. Then the known patterns of the timing of correlation sequences are looked for (a correlation of correlations) and when found can be used to estimate where the superframe boundary is which is then used to set the second node's superframe phase. Although this phase synchronisation does not take account of the unknown propagation delay between the nodes, if the strongest correlation was used then that will correspond to the nearest node, which should be within the receiving time window of the first node so that the nodes can now communicate.

### Synchronisation Source Selection

The data transmitted during a frame is provided as a means to indicate the synchronisation source of the sending node 50. Nodes advertise the quality of their own synchronisation so that, when in need, a node can choose the best neighbour and also avoid timing loops. The best neighbour is usually the one within fewest link hops of a GPS receiver with good signal coverage. If there are several neighbours in the same quality category then their contributions are averaged. In a preferred implementation, the quality of synchronisation is indicated by a hierarchy, with the best source being GPS. A typical hierarchy might be: i) local GPS, (ii) a neighbour with GPS, (iii) local Synchronous Ethernet, (iv) a neighbour with Synchronous Ethernet, (v) local PTP signal as defined by the IEEE1588 standard, (vi) a neighbour with PTP signal as defined by the IEEE1588 standard.

The control subsystem 58 of a node with local GPS will control its symbol clock 61 by locking it to the timing pulses received from the GPS. If a node loses its GPS fix then it instead will drive its symbol clock control loop with an error being the difference between a recently measured propagation delay to a neighbour and the stored average.

### Delivering Synchronisation

Each wireless node 50 provides a timing signal 72 from a timing signal output 70 of the control subsystem 58 to enable synchronisation of external equipment such as mobile base stations. Each wireless node can generate a Synchronous Ethernet clock towards external network ports. The generated Synchronous Ethernet clock is normally derived from GPS, but during GPS failure, it is derived from the best timing source currently available to the node. This could be a Synchronous Ethernet input or a clock derived from neighbouring wireless nodes over the broadband wireless link. A node may also generate a PTP signal as an alternative synchronisation option.

### Hybrid Timing Mode—Carrying a Third Party Clock

A third party clock can be transported across the network of nodes 50, whilst the network itself continues to use its own timing reference.

Two different synchronisation sources may be used simultaneously one for frequency alignment (synchronising the duration of the symbols of a superframe) and one for phase alignment (synchronising the time a superframe starts). This is referred to as a hybrid timing mode, and it enables phase and frequency synchronisation to be decoupled from each other. Decoupled in this context means that the duration of a symbol and the timing of the superframe start can be derived from different synchronisation sources. One benefit of this is that it enables different synchronisation sources to be transported across the network to those used by the network itself.

In order to operate in this way, the size of a superframe in terms of number of symbols is allowed to vary. The superframe structure incorporates leading and trailing “dead periods” of 10 μs (1000 symbols). These are shrunk or padded to vary the length of the superframe such that phase synchronisation can be maintained whilst tracking a separate symbol clock 60. In order for a downstream node 50 to be able to maintain synchronisation, an upstream node 50 that is varying its superframe length has a way of indicating to the downstream node how it has modified the superframe length. The downstream node can then use this information plus correlation sequences to measure the propagation delay and compare it against the reported reverse propagation delay and use this to correct its symbol clock 61.

Handling Large Offsets Between Synchronisation Sources when Moving Between them

The node 50 comprises a phase locked loop of which the control subsystem 58 or controller is a part. The proportional integrator controller of the control subsystem synchronises the reference source in the form of the local frequency reference 60 based on the external synchronisation information using the phase locked loop. The control subsystem uses a correction signal to control the phase locked loop. The control subsystem stepwise controls the correction signal over time. In this way, the reference source becomes synchronised with a different source external to the node while maintaining data throughput capacity with at least some of the other nodes in the network. In other words, there are no errors, packet loss or increase in latency (above the desired limits) at any time during the transition. Specifically, even when the synchronisation source is being changed, the communication link is maintained, with user data passing over it. No loss and re-establishment of the link occurs, nor any significant increase in latency (above the prescribed limit). This is an effective arrangement for entering and exiting the hybrid timing mode in which there are separate sources for phase (where the source may be from another node in the network) and frequency alignment (where the source may be SyncE). This arrangement allows large offsets to be handled between different synchronisation sources that a node wishes to transition between. This arrangement slows down (but does not dampen) the correction signal from the proportional integrator in the control loop, such that the frequency tracks in to the desired frequency, but does not change so fast that the communication link to other nodes drops. In this example, the controller stepwise controls the correction signal over time to control the phase locked loop so that the reference source changes the source external to the node to which it is synchronised over a period of time corresponding to a plurality or several frames, such as 2 to 10 frames or 3 to 7 frames. The time period of a frame is fixed between 0.5 seconds to 3 seconds, such as 1 second or 2.5 seconds. Thus, the transition between synchronisation sources typically takes 1 to 30 seconds.

### Floating Islands of Synchronisation

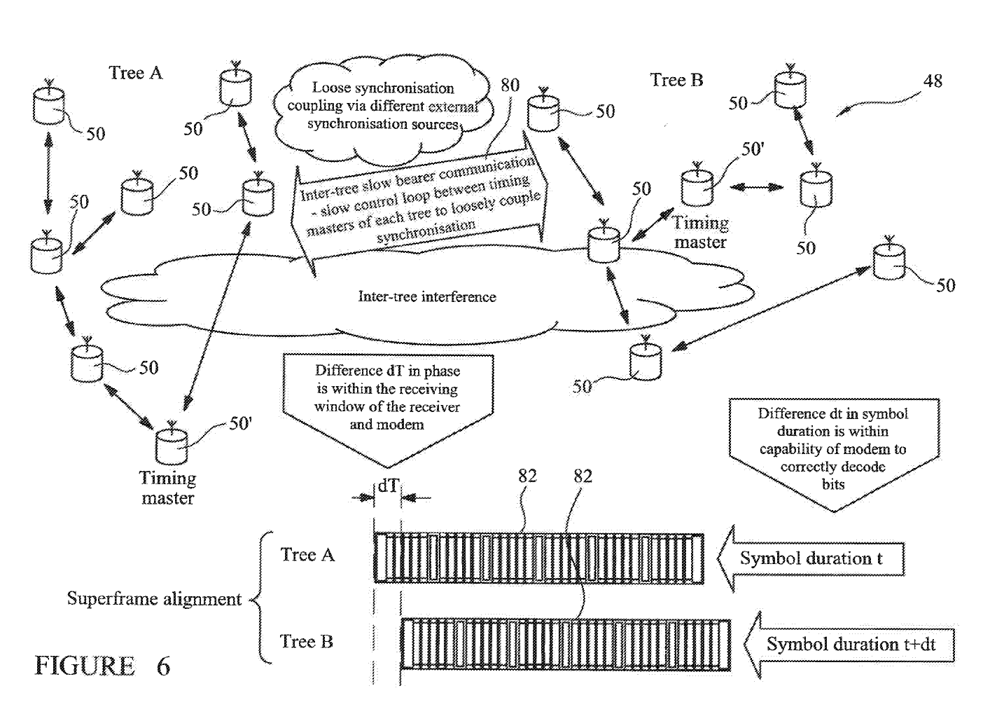

As in illustrated in FIG. 6, in the case where no node 50 in a network 48 has access to external phase timing (for example no GPS and no PTP signal as defined by the IEEE1588 standard or SyncE) or, in other words, no node of the network node can synchronise to an external synchronisation source, the nodes can still synchronise to each other using the arrangements described below. This is by one node of a group of nodes of the network being elected or selected as a master node 50′ or timing master, which node then defines the phase for the other nodes in the group of nodes to synchronise to. In this way, a node becomes or acts as a master node and synchronises with other nodes forming slave nodes to it if a predetermined condition in the form of no node of the network node being able to synchronise to an external synchronisation source applies.

A node may be selected as the master node from the group of nodes if it has access to the highest quality external synchronisation source of the group of nodes, such as a wired connection to a precision time protocol, PTP, signal or the highest quality global positioning system of the group of nodes; or a unique identifier that meets a predetermined condition, such as the unique identifier is numerically the lowest or highest of the group of nodes.

This election or selection of a master node may be arbitrary, for example by comparing the unique identifiers or IDs of all the nodes 50 in a group of nodes (where each group is less than all of the nodes of the network) and choosing the lowest (or highest) in value (a node acts as master node unless and until it receives transmissions marked with an identifier or ID lower (or higher) than its own).

Alternatively a group of nodes can compare their internal clocks against the group average to see how far and how fast a symbol clock 61 is wandering from that average.

This will enable a group of nodes to agree on a stable local timing. However, that timing is not guaranteed to be absolutely “correct” (relative to Universal Time) and may be drifting at any rate relative to another external clock 61. This can be true if none of the nodes in the group has access to an external stable synchronisation source.

A node 50 can continually assess the stability of its local clock control loop by monitoring the loop error signal, giving a measure of clock quality.

### Choosing a Node as Source of Synchronisation for a Tree of Nodes

Improved synchronisation stability of a network of nodes 50 in the presence of a number of conflicting (and possibly time-varying) synchronisation sources can be achieved by selecting a node with the highest quality synchronisation source (for example, a node with wired connection such as to a PTP signal as defined by the IEEE1588 standard synchronisation source or SyncE signal, or good local GPS coverage), and making this the master node for its local “tree” of nodes or group of nodes of the network. This can be any node in a “tree” or group, not just the wired node. Any node can become the “base” of the tree or master node of the group of nodes of the network simply by arrangement without changing any of the connections between nodes. Synchronisation between nodes is then maintained as described above.

### Loosely Coupled Synchronisation Between Trees of Nodes

Synchronisation of two or more distinct trees or groups of nodes 50 can be loosely coupled, such that they are able to vary relative to each other over short time periods, however over a longer time period on average they are tied. In a network of nodes using time division multiple access (TDMA), this allows interference management by scheduling to be effective (since the timing of transmission slots in a loosely coupled neighbouring tree of nodes can be known within a reasonable degree of accuracy), and also enables the possibility for low-capacity or slow bearers 80 to be operated between nodes in separate synchronisation groups (separate trees—Tree A and Tree B of the example of FIG. 6), allowing for exchange of information that can be used for improved interference management and overall system optimisation. A plurality of different means may be provided to achieve this loose coupling of synchronisation. They may be used individually or together. For example, a combination of different external synchronisation sources, together with low-capacity bearer communications, which may be used together to assess clock offsets and drifts between distinct trees of nodes, and slowly or stepwise correct them over time such that the maximum clock offset is within an acceptable margin to allow improved inter-tree interference management or in other words management of interference between neighbouring groups of nodes 50 of the network with different master nodes 50′. In this way, in summary, each node communicates with other nodes of the network of nodes such that reference sources of the nodes of different groups of nodes of the network are stepwise adjusted, changed, varied or altered towards synchronisation. The stepwise adjustment may be based on differences between reference sources and rate of change of differences between reference sources of the nodes of the different groups of the nodes of the network. The synchronisation level can be maintained as illustrated in FIG. 6 such that the difference dt in symbol duration t of a superframe between trees or groups of nodes is within the capability of a modem of the transceiver 52 of the node to correctly decode bits of the superframe 82 and the difference in phase dt of the superframe at different trees of nodes is within the receiving window of the receiver and modem of the transceiver of the node.

### Transition Between Synchronisation States

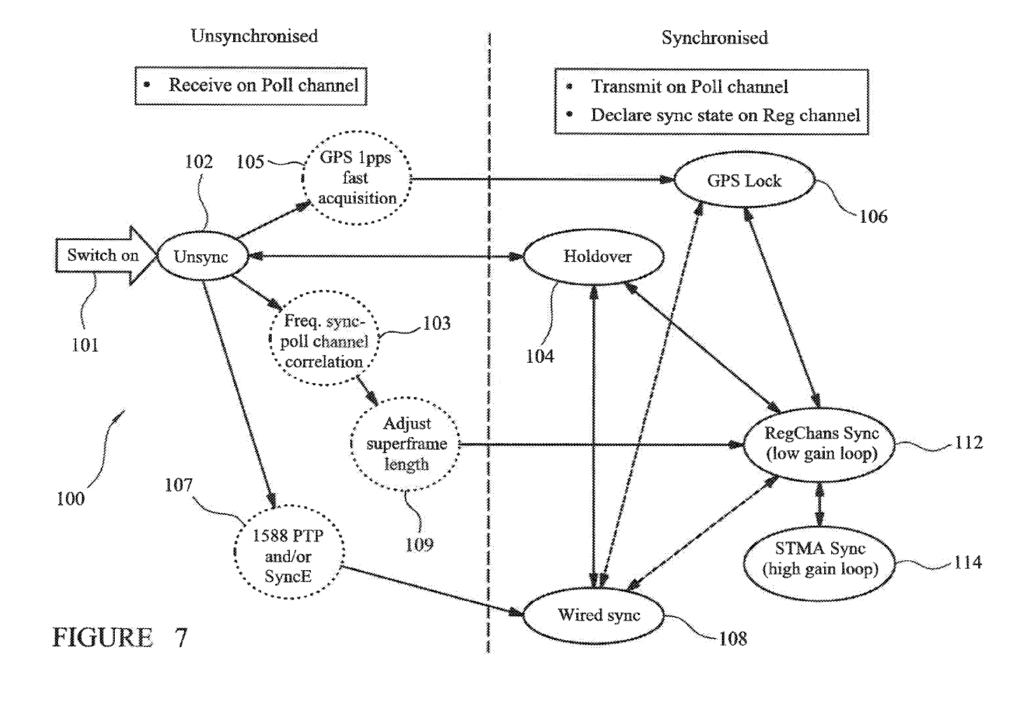

FIG. 7 is a state diagram 100 showing the different states of synchronisation in which the node 50 of FIG. 5 can exist under the control of the control subsystem 58. When a node is first switched on or booted up 101, it enters an unsynchronised state 102. It remains in this state until synchronisation is achieved, and re-enters this state if holdover 104 (a synchronisation state described further below) times out. A node in the unsynchronised state will deactivate its transmitter of transceiver 52, but will maintain receiver activity of transceiver 52 in order to listen to the poll channel 103 and begin the process of acquiring synchronisation. At the same time, the node will also look 107 for a PTP master on the wired network. This will be carried out in parallel with monitoring 105 the GPS module or GPS receiver 64 to check if it announces that it has achieved lock (in which case, this can be used for synchronisation).

If a node 50 is synchronised, it uses the Poll channel to transmit a correlation sequence 103. This sequence is unique and used only for Poll channel, by all nodes. A node without GPS or a wired source of synchronisation initially listens constantly for the Poll channel correlation sequences. By comparing an approximate superframe's-worth of correlation slots with those from the next superframe, it can tune the frequency of its symbol clock 61. During this period, the node is scanning across all antennas 56 of the node in turn. This increases the time taken but ensures that all potential opportunities are sampled.

The Poll channel slots are arranged in a pattern within the superframe, and the pattern for the slots relating to each antenna 56 position is unique. It is therefore possible to work out by observing the pattern of slots, which antenna 56 is being used by the transmitting node 50, and where the superframe boundary is and therefore recover phase synchronisation.

Each correlation sequence pattern is repeated 16 times in a superframe. A node 50 without synchronisation then adjusts the superframe length 109 (just for one superframe) such that the next superframe will start at the calculated superframe boundary. The node pair now agree on the timing of the frame boundary, excluding the effect of propagation delay—however RegChans can cope with that extent of timing offset, so this is not a problem for the next stage. The nodes are now able to proceed to establishing a RegChan 112 between them, which is a synchronisation state as explained further below.

Holdover 104 is a synchronisation state which is entered when a synchronised node 50 loses contact with any synchronisation source (local GPS, wired synchronisation source, RegChans with synchronised neighbour). The state relies on the stability of the local frequency reference or VCXO 60 within the node. This will drift over time, and so at some point communications will become non-viable due to the relative drift of symbol clocks 61 and/or superframe phase. A timeout is implemented such that after a configurable period in Holdover state, the node switches to unsynchronised state 102.

A number of different synchronisation sources can be available to a node 50, both local or internal and remote or external, namely: local GPS; Neighbours—STDMA; Neighbours—RegChans; IEEE1588v2 PTP protocol; and Synchronous Ethernet (SyncE).

The availability and quality (and therefore reliability) of these sources can vary over time. The node 50 has a means in the form of the control subsystem 58 to select between synchronisation sources, move smoothly between them, and evaluate their reliability over time. A simple solution is to have a static priority list stored in a store of the controller subsystem 58 which may be configurable. An alternative solution is to base the choice on a quality metric implemented by the controller subsystem which may be based on factors such as direct measurements of GPS signal quality and the number of hops from the most reliable timing source, or how a local clock 60 is deviating from the average of neighbouring node clocks, or by monitoring the error signal of the local control loop to evaluate the magnitude of deviations of this signal.

A node 50 receiving a good quality GPS signal will enter GPS Lock state 106 from an unsynchronised state to the synchronised state. It will use a one pulse per second signal derived from the GPS receiver 64 to directly synchronise the superframe phase and frequency. Frame alignment is done by restarting the superframe. This is known as fast acquisition and is the process 105 that occurs from the unsynchronised state 102. The node can then establish RegChans with neighbours (state 112) as described below.

If a node 50 is a wired node and is able to recover IEEE1588 synchronisation (PTP) from its wired connection, it can recover frequency and phase synchronisation by this method. If a node is a wired node and has a wired SyncE connection, it can recover frequency synchronisation from this source. However, it must have phase synchronisation from another source, since SyncE does not provide this. Either of these sources allows it to enter Wired sync state 108. The node can then establish RegChans with neighbours (state 112) as described below.

In the event that no node 50 has GPS or a source of a master IEEE1588 PTP timing signal, a number of wired nodes can elect a master which other wired nodes synchronise to via PTP. This is achieved by all wired nodes broadcasting their Global Unique Identifier (GUID). If a wired node does not then see any transmissions from GUIDs lower than its own, then it becomes the local timing master. Remote (unwired) nodes synchronise to their neighbours as before. This method can further be used to achieve a more stable synchronisation in situations where the quality of synchronisation sources for a group of nodes is fluctuating significantly (for example, where every node in a network has poor GPS signal). In this case, the node with the most reliable synchronisation can be elected master and all other nodes synchronise to it, even if they have other synchronisation sources available—this avoids instability where some nodes may temporarily switch to other less stable synchronisation sources, which can cause disturbance of data transmission. The node maintains data throughput capacity with at least some of the other nodes in the network while it synchronises.

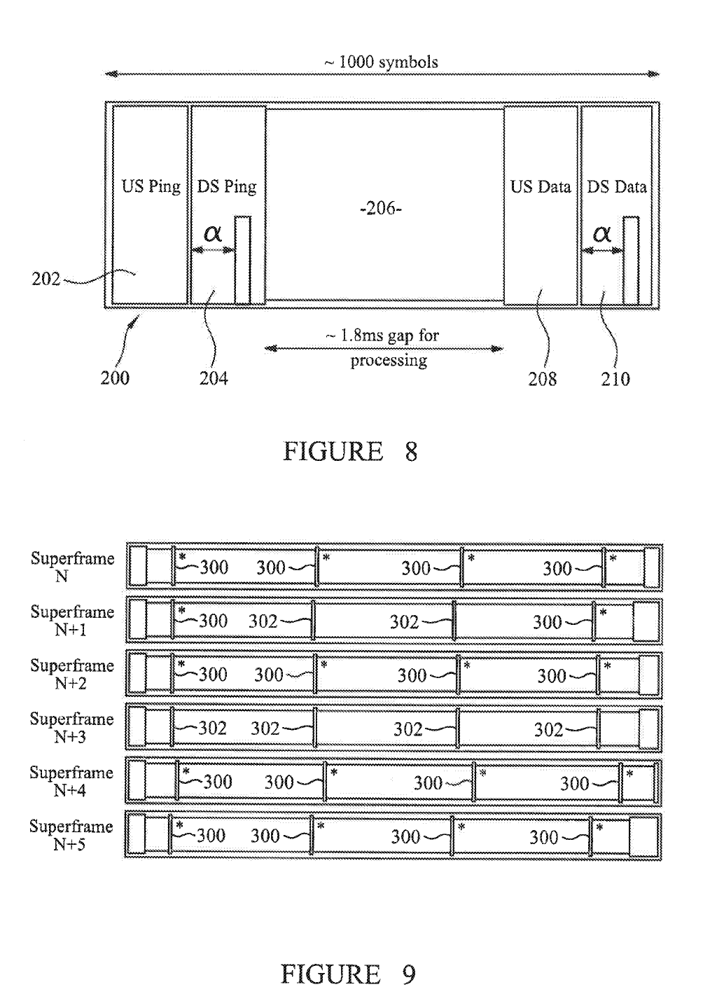

The main arrangement for unwired nodes 50 without a good GPS to obtain or maintain synchronisation is the Registration Channel (RegChan) (state 112 of FIG. 7). RegChan slots 200 are illustrated in FIG. 8. They contain upstream (US) pings 202 and downstream (DS) pings 204, followed after an interval 206 of approximately 1.8 ms (to allow for processing) by US data blocks 208 and DS data blocks 210 (FEC blocks). At this stage, which node is “US” and which is “DS” is decided by GUIDs. The lowest GUID is US. The pings are correlation sequences which allow the receiving node to work out where the symbol edges are. The arrival time of the correlation ping also allows the node to calculate a, the propagation delay (+ clock difference). The node will also then know when the corresponding forward error correction (FEC) block of the Regchan slots will arrive. The FEC blocks have a leading sequence of correlation symbols for fine tuning of symbol timing, followed by payload data.

The Registration Channel (Regchans) is used for: Link setup messages between Managers running on nodes; heartbeat messages containing the following: measurements of the reverse link propagation delay; and identification of the node's synchronisation source mainly for the purpose of avoiding synchronisation loops.

A node 50 can maintain up to 6 radio RegChans at any time with neighbours, plus any number of wired RegChans (RegChans can also be established over wired Ethernet links between nodes). The number of radio RegChans is limited by the potential for interference (collision) between RegChans.

Once a RegChan is established between two nodes 50, both nodes can calculate by exchange of messages what the true average propagation delay (+ clock difference) is between them. Individual measurements of propagation delay can then be compared against the average to work out an error value which is sent to the Phase Locked Loop (PLL) to adjust the symbol clock 60. The average is also updated. Averaging can be made over measurements from several neighbours for greater reliability.

A neighbour node 50 can declare its synchronisation state in the RegChans payload, from this a receiving node 50 can work out how many hops away the synchronisation source is for a particular RegChan, and use this information to either include or exclude the measurement in its averaging. The main purpose of this however is to avoid synchronisation loops.

The node 50 pair now agree on the true timing of the frame boundary, are using RegChans to maintain synchronisation of their symbol clocks 61, and move into Regchans sync state 112. Once synchronisation has been achieved, in the absence of a viable local synchronisation source, maintenance of synchronisation can be moved over to the STDMA schedule 114. This has three main advantages over use of RegChans for maintaining synchronisation as follows. The STDMA schedule has fewer (intra-system) collisions than RegChans. The STDMA schedule mechanism for frequency tuning is higher gain (since propagation delay measurements happen at a higher rate) than RegChans, and so is able to track deviations more effectively (it can tolerate sharper deviations). All nodes in a tree can derive their synchronisation from a single node with the best synchronisation source, providing a more stable synchronisation particularly when there are multiple conflicting synchronisation sources in the network.

RegChans are more robust in the sense that they are static, and are always transmitted in Quadrature Phase Shift Keying (QPSK) with maximum FEC protection. However, there are fewer of them. The STDMA transmissions provide a propagation delay measurement—the original propagation delay assumed while constructing the schedule, plus a timing adjustment which is provided by the modem at the time of transmission. Each measurement is then compared against the average from RegChans to provide an error signal into the Phase Locked Loop, to correct the symbol clock 60, then the phase can be ready-reckoned (a look up table of the control subsystem 58 may be used). Once STDMA synchronisation is achieved, the system moves into STDMA synchronisation state 114 and RegChans 112 are no longer used for synchronisation. If a link that a node 50 is relying on for STDMA maintenance of synchronisation becomes unreliable, the node will switch back to RegChans synchronisation state 112 to use RegChans for synchronisation maintenance.

A node 50 operating on an STDMA schedule can choose to move to using STDMA propagation measurements to maintain synchronisation. A node with local GPS signal will usually use this to maintain frequency and phase synchronisation, since this will generally be the most reliable timing source available. However, there are circumstances in which the GPS signal may be less reliable or unavailable (for example due to clutter and obstructions interrupting the direct line of sight (LOS) path to a satellite from the node GPS antenna of the GPS receiver 64). In this case, the node can be configured to ignore its local GPS source and instead use STDMA links 114 with neighbours to maintain synchronisation. It is also possible for the node to use a quality metric from the GPS receiver or sub-system to make a decision as to whether to use this local GPS source or not. A node with a wired connection providing IEEE1588 PTP can use this to maintain frequency and phase synchronisation. A node with a wired connection providing SyncE can use this to maintain frequency synchronisation. If phase synchronisation is already achieved, this will be enough to maintain both frequency and phase synchronisation (phase by dead reckoning).

In some circumstances (for example, transparent passing of SyncE), separate synchronisation sources for the symbol clock 61 and for the superframe phase are used. This is a hybrid timing mode in which separate symbol and phase synchronisation sources are used. This is an important feature to the successful and robust operation of the synchronisation mode that provides a robust way of communicating downstream the total number of transmitted symbols. In order to operate this successfully, the size of a superframe in terms of number of symbols is allowed to vary. Different superframes comprise different numbers of symbols and each at least some of the superframes comprise a plurality of indications of the number of symbols in the superframe spaced apart at different portions of the superframe. The superframe structure already incorporates leading and trailing “dead periods” of 10 μs (1000 symbols). These are shrunk or padded to vary the length of the superframe such that phase synchronisation can be maintained whilst tracking a separate symbol clock. In order for a downstream node 50 to be able to maintain synchronisation, an upstream node that is varying its superframe length must have a way of indicating to the downstream node how it has modified the superframe length. The downstream node then uses this information plus the RegChans correlation sequences to measure the propagation delay and compare it against the reported reverse propagation delay and use this to correct its symbol clock 61.

If a downstream node loses local GPS signal at the GPS receiver 64, and then misses one superframe of RegChans and STDMA slots (due to interference and/or fading) then it may lose its ability to track phase by dead reckoning (if the relative clock drift in the period is greater than 20 symbols), and therefore drop the link.

This is a potential problem of this approach. However, advantageously, this problem may be solved if each node 50 has potential paths to multiple neighbour nodes 50, since this increases the number of available RegChans, and also reduces the chances that all of these RegChans will be interrupted during the same superframe.

A simplified example of this approach is illustrated in FIG. 9. FIG. 9 illustrates six successive superframes (superframes N, N+1, . . . , N+5). The thin lines 300, 302 in FIG. 9 represent RegChans and STDMA slots relating to communications between the upstream and downstream node 50. Lines 300 with an asterisk beside them are successfully received, and the lines 302 without an asterisk beside them are missed, possibly due to interference and/or fading.

In superframe N+1, some of the transmissions are missed (lines 302), however some are successfully received (lines 300), therefore the downstream node is still able to adjust its clock 61, and also know when the current superframe will end and, therefore, when the next one will start. It therefore knows when the next transmissions will arrive.

In superframe N+3, all transmissions are missed (lines 302). In this situation, the node 50 goes into holdover (state 104), and also cannot be sure when the current superframe will end. Due to relative clock drift of the clock 61, it may therefore miss the transmissions in superframe N+4, and if this happens, leases will expire and the link will drop. After 20 seconds, the node will fall out of holdover and become unsynchronised (state 102).

A robust arrangement for communication downstream has a node 50 transmitting the total number of symbols it has transmitted. This allows downstream nodes 50 to work out from where it has received the superframe structure even if it misses RegChans and STDMA transmissions.

The method carried out by the controller subsystem 58 on the node 50 may be implemented in hardware or in software as a computer program. The computer program for implementing the method may be on a non-transitory computer readable medium such as ROM or RAM.

It should be appreciated that, with the exception of any mutually exclusive features, any combination of one or more optional features are possible.

Embodiments of the present invention have been described. It will be appreciated that variations and modifications may be made to the described embodiments within the scope of the present invention.

1-66. (canceled)

67. A node for a communications system comprising a network of a plurality of nodes, the node being configured to communicate with other nodes in the network, the node comprising:
a reference source to synchronise with other nodes in the network;
a phase locked loop to synchronise the reference source based on synchronisation information received by the node from a source external to the node; and
a controller that stepwise controls a correction signal over time to control the phase locked loop so that the reference source becomes synchronised with a different source external to the node while maintaining data throughput capacity with at least some of the other nodes in the network.

68. A node according to claim 67, wherein the node communicates with other nodes in the network using information formatted into superframes comprising a plurality of symbols in which part of the superframes are for payload data and part of the superframes are for synchronisation data and each superframe spans a frame with a time period.

69. A node according to claim 68, wherein the controller stepwise controls the correction signal over time to control the phase locked loop so that the reference source changes the source external to the node to which it is synchronised over a period of time corresponding to a plurality of frames, such as 2 to 10 frames or 3 to 7 frames.

70. A node according to claim 68, wherein the time period is fixed between 0.5 seconds to 3 seconds, such as 1 second or 2.5 seconds.

71. A node according to claim 67, wherein the source external to the node comprises a precision time protocol, PTP, signal.

72. A node according to claim 67, wherein the source external to the node comprises a synchronous ethernet, SyncE, signal.

73. A node according to claim 67, wherein the reference source comprises a clock, such as a voltage controlled crystal oscillator, VCXO.

74. A node according to claim 67, wherein the controller comprises a proportional integrator controller.

75. A node according to claim 67, wherein the node further comprises an internal synchronisation source; and the internal synchronisation source is configured to form a selected synchronisation source.

76. A node according to claim 75, wherein if it is not possible that the selected synchronisation source availability and reliability is above a predetermined level, the node is configured to synchronise with the internal synchronisation source and communications data of a superframe is interpretable until the reliability of the internal synchronisation source falls below a predetermined level.

77. A node according to claim 75, wherein the internal synchronisation source comprises a satellite positioning system receiver, such as global positioning system, GPS, receiver.

78. A node according to claim 67, wherein the network is a mesh network.

79. A network comprising a plurality of nodes according to claim 67.

80. A node for a communications system comprising a network of a plurality of nodes formed into groups of nodes, wherein the node comprises a reference source and wherein the node is configured to communicate with other nodes of the network of nodes such that reference sources of the nodes of different groups of nodes of the network are stepwise adjusted towards synchronisation.

81. A node according to claim 80, wherein the reference source of the node is stepwise adjusted based on differences between reference sources and rate of change of differences between reference sources of the nodes of the different groups of the nodes of the network.

82. A node for a communications system comprising a network of a plurality of nodes, the node comprising a reference source and being configured to receive external synchronisation information from an external synchronisation source to synchronise the reference source to the external synchronisation source; and wherein the node is configured to become a master node and synchronise other nodes forming slave nodes to it in which the slave nodes are selected from a group of nodes of the network of the plurality of nodes of which the node is a part if a predetermined condition applies.

83. A node according to claim 82, wherein the predetermined condition is that no node of the network node can synchronise to an external synchronisation source.

84. A node according to claim 82, wherein the node is configured to be selected as the master node from the group of nodes as it has access to the highest quality external synchronisation source of the group of nodes, such as a wired connection to a precision time protocol, PTP, signal or the highest quality global positioning system of the group of nodes.

85. A node according to claim 82, wherein nodes of different groups of nodes communicate such that reference sources of the different groups are stepwise adjusted towards synchronisation.

86. A node according to claim 85, wherein the reference source of the node is stepwise adjusted based on differences between reference sources and rate of change of differences between reference sources of the nodes of the different groups of the nodes of the network.
